(19) United States
(12) Patent Application Publication
(10) Pub. No.: US 2020/0294819 A1
(43) Pub. Date: Sep. 17, 2020

(54) Systems and Methods for Substrate Cooling

(71) Applicant: Nissin Ion Equipment Co., Ltd., Minami-Ku-Kyoto (JP)

(72) Inventors: Sami K. Hahto, Nashua, NH (US); George Sacco, Ipswich, MA (US); Matthew C. Farrell, Salem, MA (US); Dean Giolas, Boylston, MA (US)

(21) Appl. No.: 16/299,507

(22) Filed: Mar. 12, 2019

(51) Int. Cl. H01L 21/67; H01L 23/467

(52) U.S. Cl. CPC H01L 21/67017; H01L 23/467; H01L 21/67201

(57) ABSTRACT

An apparatus is provided for cooling a substrate. The apparatus includes a chamber configured to receive the substrate. The chamber comprises multiple sidewall sections surrounding the substrate and oriented in a vertical direction substantially parallel to a vertical side surface of the substrate. The apparatus also includes at least one gas inlet port on a first side wall section of the chamber. The gas inlet port is configured to introduce a cooling gas into the chamber in a lateral direction parallel to top and bottom surfaces of the substrate. The apparatus further includes at least one gas outlet port on a second side wall section of the chamber located substantially opposite of the first side wall section of the chamber with the substrate disposed therebetween. The gas outlet port is configured to conduct at least a portion of the cooling gas out of the chamber along the lateral direction.

### FIELD OF THE INVENTION

The invention relates generally to an apparatus and a method for cooling a substrate, such as a semiconductor wafer.

### BACKGROUND OF THE INVENTION

A semiconductor device is generally fabricated by repetitively performing a series of processes, such as photolithography, diffusion, etching, ion implantation, deposition, and metallization processes, on a substrate (e.g., a wafer). The manufacturing equipment for fabricating a semiconductor device includes apparatus for performing each of these processes, such as a process chamber into which a substrate is loaded to perform each process. Further, semiconductor device manufacturing equipment can also include at least one load lock chamber connected to a process chamber, a cassette or carrier that can hold a number of substrates, and a mechanical transfer mechanism for moving substrates among different equipment, including the process chamber and the load lock chamber.

In a typical semiconductor fabrication operation, at least one substrate is loaded onto a cassette and moved from an input stage into the load lock chamber while the load lock chamber is vented to atmosphere. The load lock chamber is then pumped down to a desired high vacuum pressure. Thereafter, the substrate in the load lock chamber is mechanically transferred to a process chamber for processing, where the substrate is subjected to high processing temperature. When processing is completed, the substrate is moved from the process chamber and placed into a cooling station prior to returning the substrate to the load lock chamber. Cooling of a substrate is necessary to avoid damaging temperature-sensitive apparatus associated with handling post-process wafers. Exemplary temperature-sensitive apparatus include, but are not limited to, the atmosphere robot arm and its associated components, as well as plastic wafer storage cassettes. After cooling, the substrate is transferred back to the original cassette located in the load lock chamber. Subsequent to the other substrates in the load lock chamber being processed in a similar manner, the load lock chamber is vented to atmospheric pressure.

A load lock chamber thus functions as a transition chamber between the process chamber, which is maintained under vacuum, and the input stage, which is under atmospheric pressure. A load lock chamber allows substrates to be transferred into the process chamber without venting the process chamber to atmosphere, thereby reducing processing times in the process chamber and minimizing exposure of the process chamber to atmospheric contamination.

### SUMMARY OF THE INVENTION

The present invention provides a load lock chamber with integrated cooling capability. Specifically, the cooling systems and methods of the present invention is implemented in a load lock chamber to take advantage of the mechanisms that are already in place (e.g., the existing gas delivery system) and can be adapted for cooling a substrate. This integrated apparatus increases system throughput and decreases physical footprint because processed substrates can be transferred from a process chamber into a load lock chamber without the need for separate cooling. Further, the systems and methods of the present invention facilitates uniform cooling of a substrate in the load lock chamber.

In one aspect, the invention features an apparatus for cooling a substrate having (i) a top surface and a bottom surface and (i) at least one vertical side surface corresponding to a substrate thickness. The apparatus comprises a chamber configured to receive the substrate. The chamber comprises a plurality of sidewall sections surrounding the substrate and oriented in a vertical direction substantially parallel to the vertical side surface of the substrate. The apparatus also includes at least one gas inlet port on a first side wall section of the chamber. The gas inlet port is configured to introduce a cooling gas into the chamber in a lateral direction parallel to the top and bottom surfaces of the substrate. The apparatus further includes at least one gas outlet port on a second side wall section of the chamber located substantially opposite of the first side wall section of the chamber with the substrate disposed therebetween. The gas outlet port is configured to conduct at least a portion of the cooling gas out of the chamber along the lateral direction. The gas inlet port and the gas outlet port, in combination, are adapted to cause the cooling gas to cooperatively flow across the top and bottom surfaces of the substrate in the lateral direction to cool the substrate.

In another aspect, a method is provided for cooling a substrate having (i) a top surface and a bottom surface and (i) at least one vertical side surface corresponding to a substrate thickness. The method includes securing the substrate in a chamber. The chamber comprises a plurality of sidewall sections surrounding the substrate and oriented in a vertical direction substantially parallel to the vertical side surface of the substrate. The method also includes introducing, via at least one gas inlet port, a cooling gas into the chamber in a lateral direction parallel to the top and bottom surfaces of the substrate. The gas inlet port is located on a first side wall section of the chamber. The method further includes conducting, via at least one gas outlet port, at least a portion of the cooling gas out of the chamber along the lateral direction. The gas outlet port is located on a second side wall section of the chamber substantially opposite of the first side wall section of the chamber with the substrate disposed therebetween. The method also includes cooling, by a flow of the cooling gas from the gas inlet port to the gas outlet port, the top and bottom surfaces of the substrate along the lateral direction.

Any of the above aspects can include one or more of the following features. In some embodiments, the at least one gas outlet port is substantially aligned with the substrate in the vertical direction to facilitate cooling of the top and bottom surfaces of the substrate. In some embodiments, the at least one gas inlet port is substantially aligned with the substrate in the vertical direction.

In some embodiments, at least one bumper is provided that is located in the chamber. The bumper is raised in the vertical direction to prevent lateral movement of the substrate caused by the cooling gas flow. In some embodiments, the bumper is integrated with a pad in the chamber on which the substrate is placed.

In some embodiments, a clamping pin is provided that is located in the chamber. The clamping pin is adapted to exert a physical pressure on the substrate in the vertical direction to prevent at least one of a vertical or lateral movement of the substrate caused by the cooling gas flow. In some embodiments, the clamping pin is retractable in the vertical direction.

In some embodiments, at least one second gas inlet port is provided that is located on a top wall of the chamber. The second gas inlet port is configured to introduce a second gas into the chamber in the vertical direction. In some embodiments, the second gas inlet port is adapted to conduct the second gas to exert a gas pressure on the substrate in the vertical direction to prevent at least one of a vertical or lateral movement of the substrate in the chamber.

In some embodiments, the chamber is a load lock chamber. In some embodiments, one or more valves are included in a gas delivery system and are in fluid communication with the gas inlet port. The valves are adjustable to provide variable flow rate of the cooling gas via the gas inlet port to control a cooling rate of the substrate.

Other aspects and advantages of the present invention will become apparent from the following detailed description, taken in conjunction with the accompanying drawings, illustrating the principles of the invention by way of example only.

### BRIEF DESCRIPTION OF THE DRAWINGS

The advantages of the technology described above, together with further advantages, may be better understood by referring to the following description taken in conjunction with the accompanying drawings. The drawings are not necessarily to scale, emphasis instead generally being placed upon illustrating the principles of the technology.

FIGS. 1a and 1b show a perspective view and a profile view, respectively, of an exemplary integrated load lock chamber, according to some embodiments of the present invention.

FIG. 2 shows an exemplary arrangement of multiple gas inlet ports on the first sidewall section of the integrated load lock chamber of FIGS. 1a and b, according to some embodiments of the present invention.

FIG. 3 shows another exemplary arrangement of multiple gas inlet ports on the first sidewall section of the integrated load lock chamber of FIGS. 1a and b, according to some embodiments of the present invention.

FIG. 4 shows an exemplary arrangement of at least one outlet port on the second sidewall section of the load lock chamber of FIGS. 1a and b, according to some embodiments of the present invention.

FIG. 5 shows another exemplary arrangement of multiple outlet ports on the second sidewall section of the load lock chamber of FIGS. 1a and b, according to some embodiments of the present invention.

FIG. 6 shows an exemplary mechanism for preventing movement of the substrate in the load lock chamber of FIGS. 1a and b, according to some embodiments of the present invention.

FIG. 7 shows another exemplary mechanism for preventing movement of the substrate in the load lock chamber of FIGS. 1a and b, according to some embodiments of the present invention.

FIG. 8 shows a retractable actuator as an example of the clamping mechanism of FIG. 7 for preventing movement of the substrate in the load lock chamber of FIGS. 1a and b, according to some embodiments of the present invention.

FIG. 9 shows yet another exemplary mechanism for preventing movement of the substrate in the load lock chamber of FIGS. 1a and b, according to some embodiments of the present invention.

FIG. 10 shows an exemplary process for cooling a substrate inside of the load lock chamber of FIGS. 1a and b, according to some embodiments of the present invention.

### DESCRIPTION OF THE INVENTION

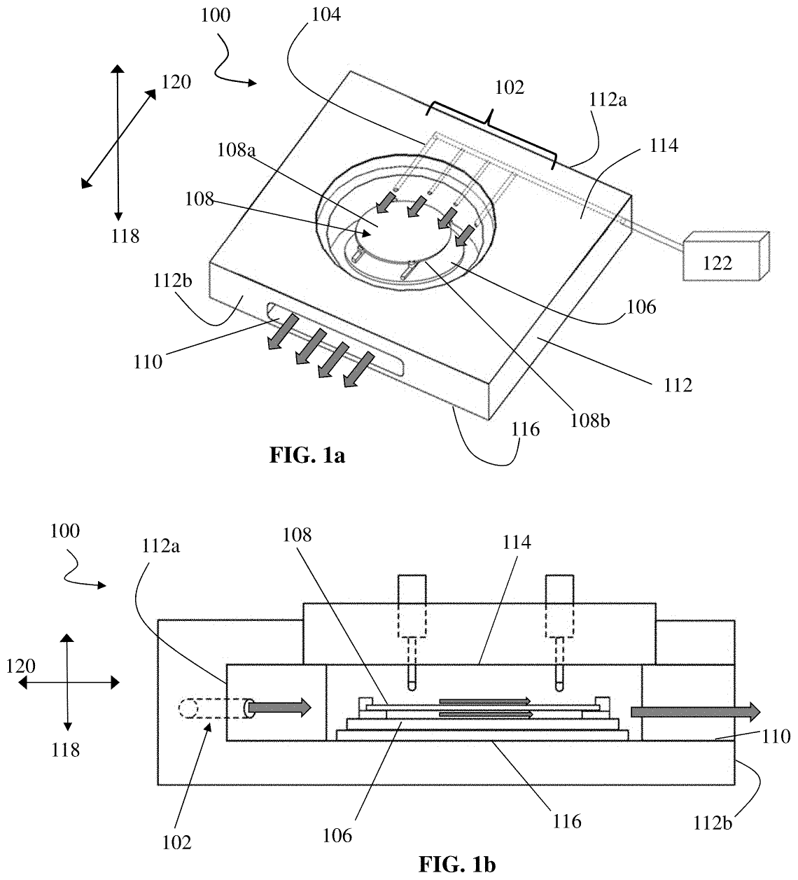

FIGS. 1a and 1b show a perspective view and a profile view, respectively, of an exemplary integrated load lock chamber 100, according to some embodiments of the present invention. Even though FIGS. 1a and 1b show the load lock chamber 100 as a single wafer device, the principles of the present invention are equally applicable to multi-wafer load lock devices, as understood by a person of ordinary skill in the art. As shown, the load lock chamber 100 includes a gas delivery manifold 102 with one or more gas inlet ports 104, a holder 106 configured to receive and store a substrate 108, and at least one gas outlet port 110. Substrate 108 generally refers to a solid substance onto which a layer of a second substance is applied. In integrate circuit fabrication, the substrate 108 can be a wafer made from a semiconductor material (e.g., silicon, silicon carbide, germanium or gallium arsenide) or an insulator material (e.g., glass). The substrate 108 has a top surface 108a and a bottom surface 108b, both of which can be substantially horizontal if the substrate 108 is planar. The substrate 108 also includes at least one vertical side surface (not labeled) corresponding to a substrate thickness.

Generally, the load lock chamber 100 is defined by multiple sidewall sections 112, a top wall 114 and a bottom wall 116 that substantially encase the substrate 108 in the holder 106. The sidewall sections 112 can be oriented in a vertical direction 118 substantially parallel to the vertical side surface of the substrate 108. The top and bottom walls 114, 116 of the chamber 100 are positioned relative to the top and bottom surfaces 108a, 108b, respectively, of the substrate 108, such as parallel to the top and bottom surfaces of the substrate 108.

The one or more gas inlet ports 104 are located on a first side wall section 112a of the chamber 100 and are configured to introduce a cooling gas, such as a nitrogen (N₂) gas, into the chamber 100 in a lateral direction 120 substantially parallel to the top surface 108a and the bottom surface 108b of the substrate 108 and perpendicular to the vertical direction 118. In general, directing a cooling gas to flow across the top and bottom surfaces 108a, b of the substrate 108 facilitates heat transfer from the substrate 108 to the gas, thereby reducing the temperature of the substrate 108.

The one or more gas outlet ports 110 are located on a second side wall section 112b of the chamber 100 and are configured to conduct at least a portion of the cooling gas out of the chamber 100 along the lateral direction 120. The second side wall section 112b is located substantially opposite of the first sidewall section 112a with the substrate 108 and the holder 106 disposed between the two sections 112a,b. This opposite-wall arrangement of the gas inlet ports 104 and gas outlet ports 110 allows at least a portion of the nitrogen gas to cooperatively flow across the top and/or bottom surfaces 108a,b of the substrate 108 to cool the substrate 108 before exiting from the chamber 100.

In some embodiments, the gas manifold 102 is configured to deliver a cooling gas to the chamber 100 to cool the substrate 108. Specifically, the gas manifold 102 can be configured to introduce as well as control the introduction of a cooling gas from at least one gas source (not shown) into the chamber 100 via one or more of the inlet ports 104 fluidly coupled to the first side wall section 112a. In some embodiments, the gas manifold 102 is connected to the same gas source (not shown) and/or delivery system (not shown) that are traditionally used by the load lock chamber 100 to deliver a gas to the chamber 100 for adjusting the internal pressure of the chamber 100. That is, the gas (e.g., nitrogen) that is typically used for restoring the internal pressure in the load lock chamber 100 from vacuum to atmospheric pressure may be used by the manifold 102 to cool the substrate 108 in the chamber 100. In some embodiments, the same gas is used for both cooling and pressure adjustment. In some embodiments, the gas manifold 102 also includes one or more valves 122 in fluid communication with one or more of the gas inlet ports 104 to control the flow rate of the gas delivered therethrough. The valves 122 are adjustable, either manually by an operator or automatically by a computer numerical controller, to provide adjustable flow rate of the cooling gas delivered via one or more of the gas inlet ports 104. This enables control of the velocity of the cooling gas, thereby providing variable cooling rate for cooling the substrate 108 in the chamber 100. In some embodiments, the substrate 108 can be cooled at different cooling rates over time in response to variable system throughput requirements by selectively manipulating the valves 122 of the manifold 102. In some embodiments, the valves 122 are adjusted to achieve turbulence in the cooling gas flow for the purpose of enhanced thermal transfer. For example, if two valves 122 are included in the manifold 102, one valve 122 can be adjusted to offer slow venting by restricting the gas flow to minimize the pressure burst into the evacuated volume, while the other valve 122 can be adjusted to offer a variable flow rate, which provides an adjustable cooling rate. The resultant gas flow can be turbulent in nature.

As shown in FIGS. 1a and 1b, the cooling gas is adapted to flow in the lateral direction 120 from the first side wall section 112a to the opposite second side wall section 112b of the chamber 100. An advantage of this lateral cooling flow, in comparison to directing the cooling gas to flow in the vertical direction 118 from the top wall 114 to the bottom wall 116 of the chamber 100, is that the substrate 108 can be cooled relatively uniformly across both its top and bottom surfaces 108a, 108b. That is, the cooling gas flow rate/velocity is substantially constant across these surfaces. For example, the cooling gas flow rate/velocity can be adjusted such that the rate/velocity across the top surface 108a of the substrate 108 is substantially the same as the rate/velocity across the bottom surface 108b of the substrate 108. Another advantage of this lateral cooling flow is that the pressure of the cooling gas does not concentrate at a particular area on the top or bottom surfaces 108a, 108b of the substrate 108 when the cooling gas is introduced into the chamber 100, thereby minimizing the likelihood of the cooling gas damaging (e.g., breaking) the substrate 108.

In some embodiments, the one or more gas inlet ports 104 and/or the one or more gas outlet ports 110 are suitably arranged on their respective sidewall sections to enhance the uniform distribution of the cooling gas across the top and bottom surfaces 108a, 108b of the substrate 108. For example, at least one gas inlet port 104 can be substantially aligned with the substrate 108 in the vertical direction 118, such as at about the same vertical height as the substrate 108 in the chamber 100, to facilitate cooling of the top and bottom surfaces 108a, 108b of the substrate 108. Likewise, at least one gas outlet port 110 can be substantially aligned with the substrate 108 in the vertical direction 118 to further enhance uniform cooling.

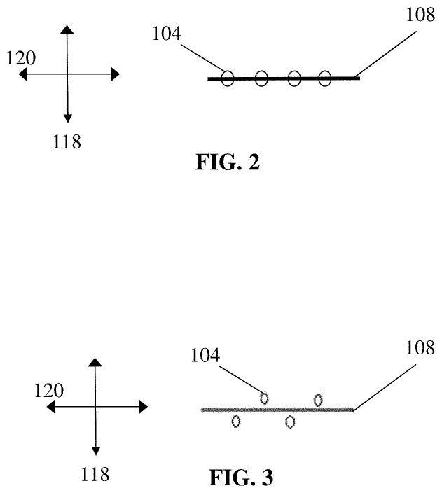

FIG. 2 shows an exemplary arrangement of multiple gas inlet ports 104 on the first sidewall section 112a of the integrated load lock chamber of FIGS. 1a and b, according to some embodiments of the present invention. As shown, multiple inlet ports 104 are substantially aligned with the substrate 108 in the vertical direction 118, such as at about the same vertical height as the substrate 108. This arrangement ensures uniform cooling of the top and bottom surfaces 108a, 108b of the substrate 108 in the holder 106. In addition, these inlet ports 104 can be evenly distributed along the width of the chamber 100 in the lateral direction 120, such that they are on either side of the substrate 108, which enhances the uniform delivery of the cooling gas through the chamber 100. Likewise, the same arrangement can be made for the gas outlet ports 110 on the second sidewall section 112b of the chamber 100 in relation to the substrate 108.

FIG. 3 shows another exemplary arrangement of multiple gas inlet ports 104 on the first sidewall section 112a of the integrated load lock chamber of FIGS. 1a and b, according to some embodiments of the present invention. As shown, an equal number of inlet ports 104 are arranged above and below the substrate 108 in the vertical direction 118 to ensure uniform cooling of the top and bottom surfaces 108a, 108b of the substrate 108 in the holder 106. These ports 104 can be offset relative to each other above and below the substrate 108. Likewise, the same arrangement can be made for the gas outlet ports 110 on the second sidewall section 112b of the chamber 100 in relation to the substrate 108.

FIG. 4 shows an exemplary arrangement of at least one outlet port 110 on the second sidewall section 112b of the load lock chamber 100 of FIGS. 1a and b, according to some embodiments of the present invention. As shown, one gas outlet port 110 is located on the second sidewall section 112b of the chamber 100 positioned at substantially the same height along the vertical direction 118 as the substrate 108 in the chamber 100. The gas outlet port 110 has a wide opening along the lateral direction 120 through which the substrate 108 can be loaded into and unloaded from the interior of the chamber 100. Thus, the gas outlet port 110 can provide the dual function of conducting the cooling gas out of the chamber 100 as well as enabling the loading and unloading of the substrate 108 relative to the chamber 100.

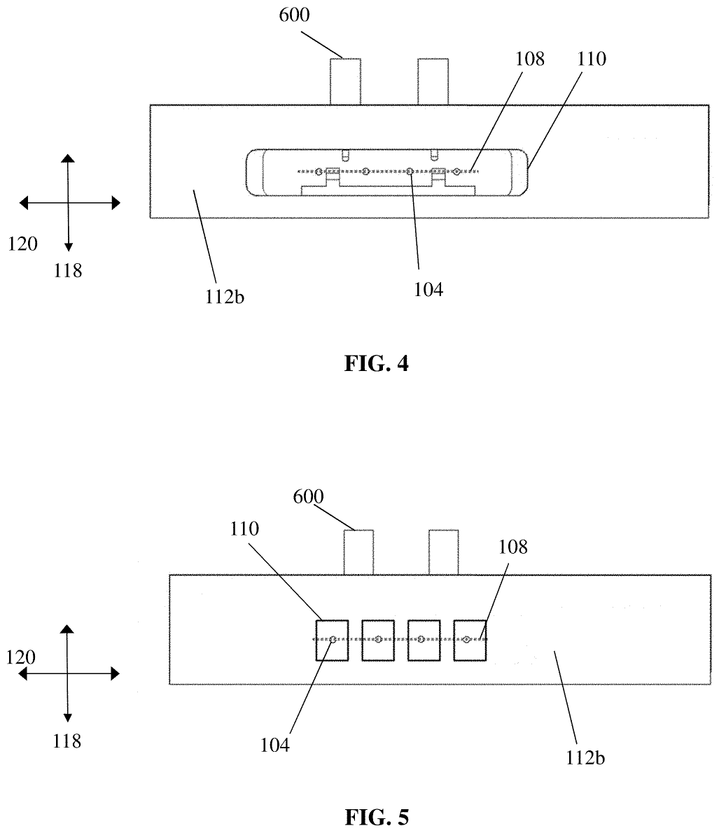

FIG. 5 shows another exemplary arrangement of multiple outlet ports 110 on the second sidewall section 112b of the load lock chamber 100 of FIGS. 1a and b, according to some embodiments of the present invention. As shown, multiple gas outlet ports 110 are aligned with the substrate 108 in the vertical direction 118, such as at about the same vertical height as the substrate 108 in the chamber 100. The gas outlet ports 110 are also evenly distributed along the width of the chamber 100 in the lateral direction 120, such that they are on either side of the substrate 108, thereby enhancing the uniform delivery of the cooling gas through the chamber 100. Likewise, the same arrangement can be made for the gas inlet ports 104 on the first sidewall section 112a of the chamber 100. In general, any reasonable arrangement of the inlet ports 104 and/or the outlet ports 110 are within the scope of the present invention to provide uniform gas flow across the top and bottom surfaces 108a, 108b of the substrate 108. Due to the small opening of each gas outlet port 110 in this exemplary configuration, a separate opening (not shown) may be disposed on another sidewall section of the load lock chamber 100 for receiving and removing the substrate 108.

In another aspect, the present invention features various mechanisms for securing the substrate 108 to the load lock chamber 100. In cases where the cooling gas flow across the substrate 108 has a high velocity, the cooling gas flow can potentially disturb and move the substrate 108. Therefore, it may be desirable to secure the substrate 108 within the chamber 100 to prevent substrate movement. However, when the velocity of the cooling gas is low, the substrate 108 is unlikely to move, thus may not need to be secured.

FIG. 6 shows an exemplary mechanism for preventing movement of the substrate 108 in the load lock chamber 100 of FIGS. 1a and b, according to some embodiments of the present invention. As shown, the substrate 108 is positioned on at least one pad 402 coupled to the holder 106 in the load lock chamber 100. The pad 402 has one or more bumpers 404, such as side walls, that are raised in the vertical direction 118 to limit a lateral sliding movement of the substrate 108 caused by, for example, the cooling gas flowing along the lateral direction 120. Thus one or more of the pad-bumper combination can be distributed around the edge/perimeter of the substrate 108 to hold the substrate 108 in place relative to the holder 106. A bumper 404 can be integrated with the pad 402 or removably attached to the pad 402.

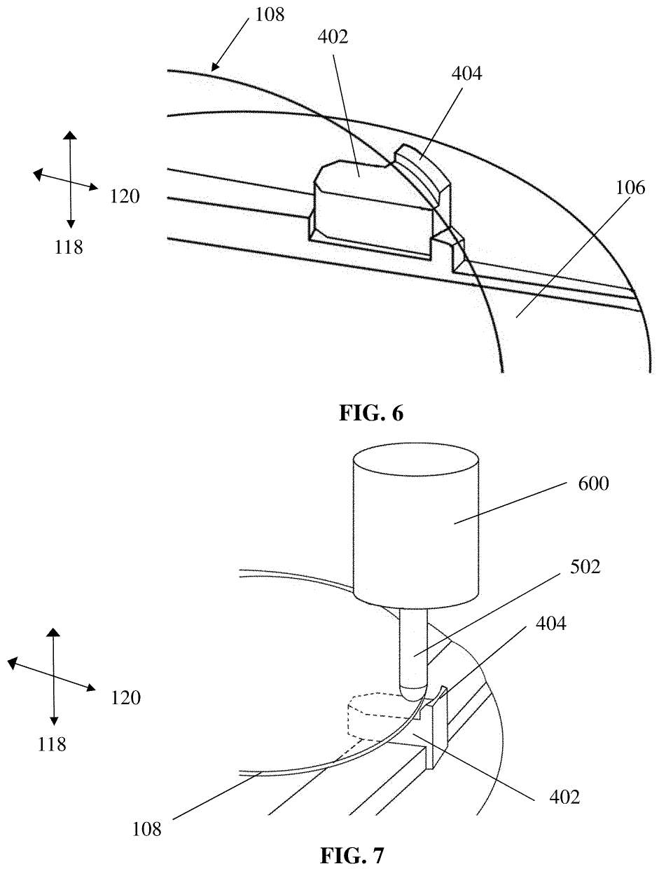

FIG. 7 shows another exemplary mechanism for preventing movement of the substrate 108 in the load lock chamber 100 of FIGS. 1a and b, according to some embodiments of the present invention. In some instances, the cooling gas flow is sufficiently fast to generate a lifting force in the vertical direction 118, which can cause the substrate 108 to jump over the bumpers 404. To prevent such lifting movement of the substrate 108 while it is positioned on the pad-bumper combination 402 and 404, a clamping mechanism is used to apply a vertical force to the top surface 108a of the substrate 108 to counteract any lifting motion by the cooling gas flow. As shown in FIG. 7, a clamping pin 502 is coupled to the top wall 114 of the load lock chamber 100 and substantially aligned with a corresponding pad 402 on the holder 106. Thus, a clamping pin 502 can be used for each pad 402. The tip 504 of the clamping pin 502 is adapted to contact the top surface 108a of the substrate 108 to exert a physical pressure on the substrate 108 in the vertical direction 118 against the pad 402, thereby preventing at least one of lateral or vertical movement of the substrate 108. In some embodiments, the pressure asserted by the clamping pin 502 prevents both lateral and vertical movement of the substrate 108. In some embodiments, the tip 504 of the clamping pin 502 is adapted to make contact with the top surface 108a of the substrate 108 at a certain tolerance distance from the edge of the substrate 108, such as at a distance of about 2 mm from the edge of the substrate 108. The clamping pin 502 does not need to be used in conjunction with the bumper 404. In some embodiments, only one or more clamping pins 502 and pads 402 are used without the pads 402 being attached to the bumpers 404.

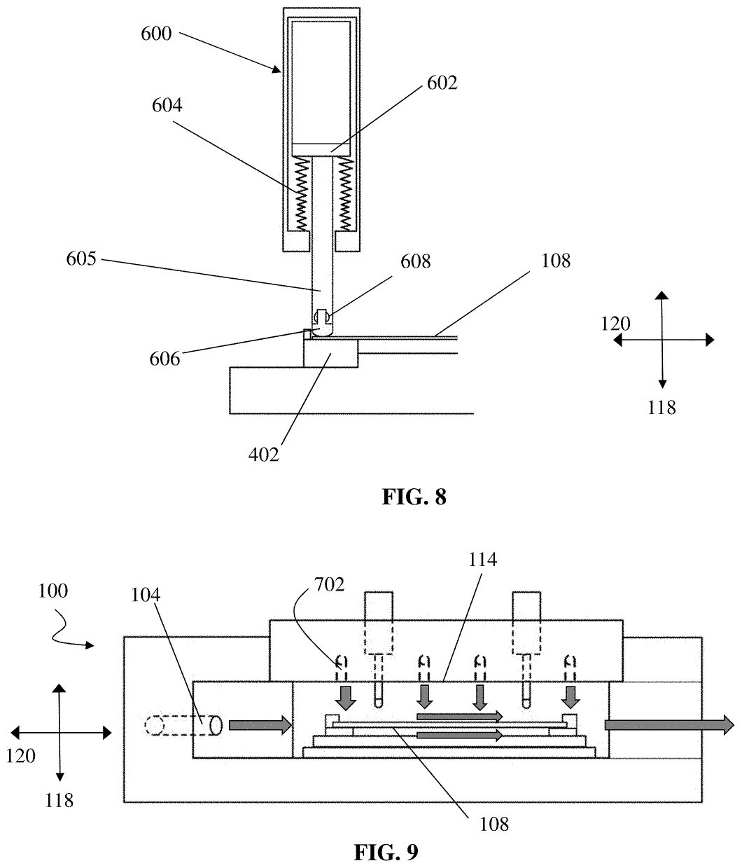

In some embodiments, the clamping pin 502 is attached to an actuator 600. FIG. 8 shows a retractable actuator 600 as an example of the clamping mechanism of FIG. 7 for preventing movement of the substrate 108 in the load lock chamber 100 of FIGS. 1a and b, according to some embodiments of the present invention. As shown, the actuator 600 includes a top portion 602 and a set of bellows 604. The clamping pin 502 includes a rod portion 605 and a tip 606 held in the rod portion 605 by a retention spring 608. In operation, air pressure is applied to the top portion 602 of the actuator 600 to compress the set of bellows 604, which pushes the rod portion 605 of the clamping pin 502 along with the tip 606 downward in the vertical direction 118 against the top surface 108a of the substrate 108. Once the air pressure is released, the rod portion 605 (along with the tip 606) of the clamping pin 502 is adapted to retract upward to release the pressure against the substrate 108. The tip 606 of the clamping pin 502 can also be replaceable. Using such a retractable actuator 600 is advantageous because an operator can choose to activate the actuator 600 to reinforce the positioning of the substrate 108 within the chamber 100 only when the cooling gas flow is fast and/or the bumper 404 is not sufficient to prevent the substrate 108 from moving. The actuator 600 can cause the clamping pin 502 to be in its retracted position when such additional securement is not needed.

FIG. 9 shows yet another exemplary mechanism for preventing movement of the substrate 108 in the load lock chamber 100 of FIGS. 1a and b, according to some embodiments of the present invention. As shown, a second flow of fluid, in addition to the lateral cooling gas flow, is provided to the load lock chamber 100 to prevent movement of the substrate 108 within the chamber 100. The vertical fluid flow can be introduced into the chamber 100 from at least one inlet port 702 located on the top wall 114 of the chamber 100. The inlet port 702 is configured to deliver the second fluid flow in the vertical direction 118, thereby exerting a vertical pressure on the top surface 118a the substrate 118 to prevent the substrate 118 from moving laterally or vertically due to, for example, the lateral gas flow introduced from the one or more gas inlet ports 104. The second fluid introduced from the inlet port 702 can be a cooling gas the same as or different from the lateral cooling gas flow from the inlet port 104. The second fluid does not need to be a cooling gas. It can be any reasonable fluid for the purpose of keeping the substrate 100 in place inside of the chamber 100. The vertical fluid flow approach can be employed in conjunction with one or more of the mechanisms described above with respect to FIGS. 6-8 to stabilize the substrate 108. Alternatively, the vertical fluid flow approach can be employed as a stand-alone mechanism for stabilizing the substrate 108 inside of the chamber 100.

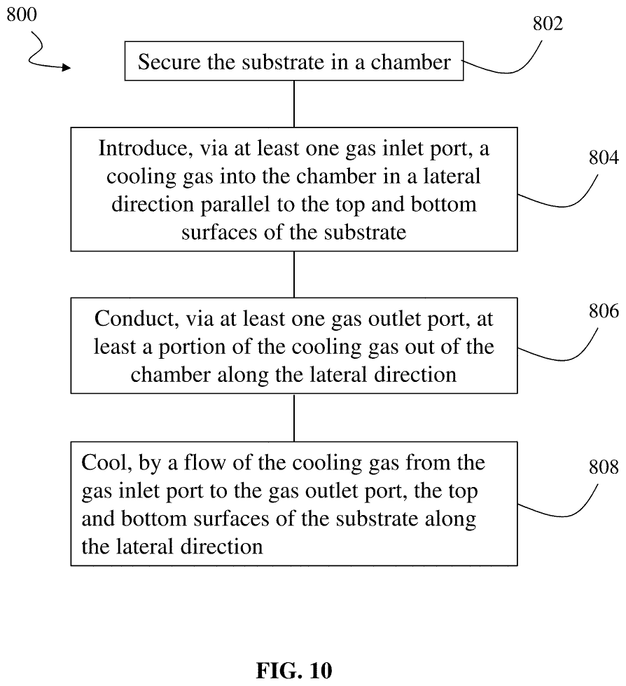

FIG. 10 shows an exemplary process 800 for cooling a substrate inside of the load lock chamber 100 of FIGS. 1a and 1b, according to some embodiments of the present invention. At step 802, the substrate 108 is secured to the holder 106 in the chamber 100 using one or more of the securing mechanisms explained above with reference to FIGS. 6-9. For example, the substrate 108 can be positioned on one or more pads 402 that are coupled to the holder 106. In some embodiments, the pads 402 are attached to one or more bumpers 404 to prevent the substrate 108 from moving laterally within the chamber, as illustrated in FIG. 6. In some embodiments, a clamping pin 502, as attached to a retractable actuator 600, is used to restrain the substrate 108 in the vertical and/or lateral directions 118, 120, as illustrated in FIGS. 7 and 8. In some embodiments, a vertical fluid flow is used to restrain the substrate 108 in the vertical and/or lateral directions 118, 120, as illustrated in FIG. 9.

At step 804, a cooling gas, such as nitrogen gas, is introduced into the chamber 100 via at least one gas inlet port 104 that is configured to conduct the gas in the lateral direction 120 substantially parallel to the top and bottom surfaces 108a, 108b of the substrate 108. The gas inlet port 104 is located on the first side wall section 112a of the chamber 100. In some embodiments, an operator can manipulate one or more valves coupled to the gas inlet port 104 to achieve a variable flow rate of the cooling gas. In some embodiments, the flow rate of the cooling gas is adjusted to create laminar or turbulent flow conditions.

At step 806, the cooling gas is adapted to exit from the chamber 100 via at least one gas outlet port 110 along the lateral direction 120. The gas outlet port 110 is located on a second side wall section 112b of the chamber 100 substantially opposite of the first side wall section 112a of the chamber 100 with the substrate 108 disposed therebetween.

Such lateral flow of the cooling gas from the inlet port 104 to the outlet port 110 is adapted to cool both the top and bottom surfaces 108a, 108b of the substrate 108 at step 808. Specifically, the gas inlet port 104 and/or the gas outlet port 110 are positioned on their respective side wall sections 112 to allow substantially uniform flow of the cooling gas across the top and bottom surfaces 108a, 108b of the substrate 108. For example, at least one of the gas inlet port 104 or the gas outlet port 110 can be positioned along its corresponding side wall section at about the same vertical height as the substrate 108 in chamber 100.

One skilled in the art will realize the invention may be embodied in other specific forms without departing from the spirit or essential characteristics thereof. The foregoing embodiments are therefore to be considered in all respects illustrative rather than limiting of the invention described herein. Scope of the invention is thus indicated by the appended claims, rather than by the foregoing description, and all changes that come within the meaning and range of equivalency of the claims are therefore intended to be embraced therein.

What is claimed:

1. An apparatus for cooling a substrate having (i) a top surface and a bottom surface and (i) at least one vertical side surface corresponding to a substrate thickness, the apparatus comprising:
a chamber configured to receive the substrate, the chamber comprising a plurality of sidewall sections surrounding the substrate and oriented in a vertical direction substantially parallel to the vertical side surface of the substrate;
at least one gas inlet port on a first side wall section of the chamber, the gas inlet port configured to introduce a cooling gas into the chamber in a lateral direction parallel to the top and bottom surfaces of the substrate; and
at least one gas outlet port on a second side wall section of the chamber located substantially opposite of the first side wall section of the chamber with the substrate disposed therebetween, the gas outlet port configured to conduct at least a portion of the cooling gas out of the chamber along the lateral direction,
wherein the gas inlet port and the gas outlet port, in combination, cause the cooling gas to cooperatively flow across the top and bottom surfaces of the substrate in the lateral direction to cool the substrate.

2. The apparatus of claim 1, wherein the at least one gas outlet port is substantially aligned with the substrate in the vertical direction to facilitate cooling of the top and bottom surfaces of the substrate.

3. The apparatus of claim 1, wherein the at least one gas inlet port is substantially aligned with the substrate in the vertical direction.

4. The apparatus of claim 1, further comprising at least one bumper located in the chamber, the bumper being raised in the vertical direction to prevent lateral movement of the substrate caused by the cooling gas flow.

5. The apparatus of claim 4, wherein the bumper is integrated with a pad in the chamber on which the substrate is placed.

6. The apparatus of claim 1, further comprising a clamping pin located in the chamber, the clamping pin adapted to exert a physical pressure on the substrate in the vertical direction to prevent at least one of a vertical or lateral movement of the substrate caused by the cooling gas flow.

7. The apparatus of claim 6, wherein the clamping pin is retractable in the vertical direction.

8. The apparatus of claim 1, further comprising at least one second gas inlet port located on a top wall of the chamber, the second gas inlet port configured to introduce a second gas flow into the chamber in the vertical direction.

9. The apparatus of claim 8, wherein the second gas inlet port is adapted to conduct the second gas flow to exert a gas pressure on the substrate in the vertical direction to prevent at least one of a vertical or lateral movement of the substrate in the chamber.

10. The apparatus of claim 1, wherein the chamber is a load lock chamber.

11. The apparatus of claim 1, further comprising one or more valves in fluid communication with the gas inlet port, wherein the valves are adjustable to provide variable flow rate of the cooling gas via the gas inlet port.

12. A method for cooling a substrate having (i) a top surface and a bottom surface and (i) at least one vertical side surface corresponding to a substrate thickness, the method comprising:
securing the substrate in a chamber, the chamber comprising a plurality of sidewall sections surrounding the substrate and oriented in a vertical direction substantially parallel to the vertical side surface of the substrate;
introducing, via at least one gas inlet port, a cooling gas into the chamber in a lateral direction parallel to the top and bottom surfaces of the substrate, the gas inlet port located on a first side wall section of the chamber;
conducting, via at least one gas outlet port, at least a portion of the cooling gas out of the chamber along the lateral direction, the gas outlet port located on a second side wall section of the chamber substantially opposite of the first side wall section of the chamber with the substrate disposed therebetween; and
cooling, by a flow of the cooling gas from the gas inlet port to the gas outlet port, the top and bottom surfaces of the substrate along the lateral direction.

13. The method of claim 12, wherein the gas outlet port is substantially aligned with the substrate in the vertical direction to facilitate uniform cooling of the top and bottom surfaces of the substrate.

14. The method of claim 12, wherein securing the substrate comprises:
placing the substrate on at least one pad in the chamber; and
preventing lateral movement of the substrate by a bumper of the pad raised in the vertical direction.

15. The method of claim 12, wherein securing the substrate comprises:
actuating a clamping pin located in the chamber to exert a physical pressure on the substrate in the vertical direction; and
preventing at least one of a vertical or lateral movement of the substrate by the clamping pin.

16. The method of claim 12, wherein securing the substrate comprises:
conducting a second gas flow into the chamber in the vertical direction via a second gas inlet port located on a top wall of the chamber; and
preventing at least one of vertical or lateral movement of the substrate by the second gas flow.

17. The method of claim 12, further comprising introducing the cooling gas into the chamber at a variable flow rate to control a cooling rate of the substrate.
